(19) United States
(12) Patent Application Publication
(10) Pub. No.: US 2015/0014742 A1
(43) Pub. Date: Jan. 15, 2015

(54) SEMICONDUCTOR DEVICE AND PRODUCTION METHOD FOR SEMICONDUCTOR DEVICE

(71) Applicant: FUJI ELECTRIC CO., LTD., Kawasaki-shi (JP)

(72) Inventor: Hong-fei LU, Matsumoto-city (JP)

(21) Appl. No.: 14/505,659

(22) Filed: Oct. 3, 2014

Related U.S. Application Data
(63) Continuation of application No. PCT/JP2013/066394, filed on Jun. 13, 2013.

(30) Foreign Application Priority Data
Jul. 18, 2012 (JP) 2012-159640

(51) Int. Cl. H01L 29/739; H01L 21/225; H01L 21/265; H01L 29/06; H01L 29/66

(52) U.S. Cl. CPC H01L 29/7393; H01L 29/0646; H01L 29/66325; H01L 21/265; H01L 21/225
USPC 257/139; 438/135

(57) ABSTRACT

Depth of a termination p base region provided in a termination portion of an active region close to an edge termination structure portion is more than depth of a p-type base region provided inside the termination p base region. An n-type high-concentration region is provided from one main surface of the semiconductor substrate in the entire surface layer of one surface of a semiconductor substrate within a depth of 20 μm or less below the bottom of the termination p base region. Ratio of the impurity concentration n₁ of the n-type high-concentration region (1c) to the impurity concentration n₂ of an n⁻ drift region satisfies 1.0<n₁/n₂≦5.0. Reverse leakage current when operation temperature of an element is high can be reduced and trade-off between on-state voltage and switching loss can be improved. Rising peak voltage of collector voltage when a semiconductor device is off is reduced.

### BACKGROUND OF THE INVENTION

A. Field of the Invention

The present invention relates to a reverse blocking IGBT which can improve a trade-off relationship among a reverse leakage current at a reverse breakdown voltage, an on-state voltage, and switching loss and a method for producing the same.

B. Description of the Related Art

A high-breakdown-voltage discrete power device plays a key role in a power conversion device. Examples of the power device include an insulated gate bipolar transistor (IGBT) and a MOS gate (metal-oxide-semiconductor insulated gate) field effect transistor (MOSFET). The IGBT is a conductivity-modulation-type bipolar device and has a lower on-state voltage than the MOSFET which is a unipolar device. Therefore, in general, the IGBT is particularly applied to a high-breakdown voltage device for switching in which the on-state voltage is likely to be high.

When a matrix converter with high conversion efficiency is used as the power conversion device, a bidirectional switching device needs to be used. A reverse blocking IGBT has drawn attention as a semiconductor device forming the bidirectional switching device. The reason is that the reverse blocking IGBTs are connected in inverse parallel to each other to simply form the bidirectional switching device. The reverse blocking IGBT is obtained by improving the pn junction between the collector region and the drift region in the general IGBT such that a reverse blocking voltage can be held by a termination structure with high breakdown voltage reliability. Therefore, the reverse blocking IGBT is suitable as a switching device provided in the matrix converter for AC-AC power conversion or a multi-level inverter for DC-AC conversion.

Next, the structure of the reverse blocking IGBT according to the related art will be described with reference to FIG. 11. FIG. 11 is a cross-sectional view illustrating the structure of a main portion of the reverse blocking IGBT according to the related art. As illustrated in FIG. 11, in the reverse blocking IGBT, similarly to the general IGBT, an active region 110 is provided in the vicinity of the center of a chip and an edge termination structure portion 120 is provided in an outer circumferential portion surrounding the active region 110. The reverse blocking IGBT further includes a isolation region 130 which surrounds the outside of the edge termination structure portion 120. The isolation region 130 includes, as a main region, a p⁺ isolation layer 21 for connecting one main surface and the other main surface of an n⁻ semiconductor substrate with a p-type region.

The p⁺ isolation layer 21 can be formed by the thermal diffusion of impurities (for example, boron) from the one main surface of the n⁻ semiconductor substrate. The p⁺ isolation layer 21 can prevent the termination of a pn junction surface between a p-type collector region 10 and an n⁻ drift region 1, which is a reverse breakdown voltage junction, from being exposed from a side end surface 12 of the chip which is a cut surface during chipping. In addition, the p⁺ isolation layer 21 causes the pn junction surface between the p-type collector region 10 and the n⁻ drift region 1 to be exposed from both the side end surface 12 of the chip and a surface 13 of the substrate (the front surface of the substrate) covered with an insulating film 14 in the edge termination structure portion 120. Therefore, it is possible to improve the reliability of the reverse breakdown voltage.

The active region 110 is a main current path of a vertical IGBT which includes a front-surface-side structure including the n⁻ drift region 1, a p-type base region 2, an n⁺ emitter region 3, a gate insulating film 4, a gate electrode 5, an interlayer insulating film 6, and an emitter electrode 9 and a rear surface structure including the p-type collector region 10 and a collector electrode 11. In addition, the depth of a termination p base region (a p base region provided in the outermost circumference of the active region 110) 2-1 provided in a termination portion 110a of the active region 110 close to the edge termination structure portion 120 is more than the depth of the p-type base region 2 provided inside the termination p base region 2-1. When the semiconductor device is turned off, holes stored in the edge termination structure portion 120 directly flow into the deep p-type base region 2. Therefore, an edge portion is less likely to be broken and the amount of current which can turn off the semiconductor device increases.

An n-type high-concentration region 1a which has a lower resistance than the n⁻ drift region 1 and is deeper than the p-type base region 2 is formed in a surface layer of a portion of the n⁻ drift region 1 which is disposed below the gate electrode 5 between the termination p base region 2-1 and the p-type base region 2 adjacent to the termination p base region 2-1. When the semiconductor device is turned on, the n-type high-concentration region 1a functions as a hole barrier and holes are stored in the n⁻ drift region 1. Therefore, it is possible to reduce the on-state voltage (for example, see JP 10-178174 A (Abstract and FIG. 1)). The distance (width) of the n-type high-concentration region 1a from the p-type base region 2 to the n⁻ drift region 1 in a direction parallel to the interface between the gate electrode 5 and the n⁻ drift region 1 is greater than the distance (thickness) thereof in the vertical direction. It is possible to further reduce the resistance (JFET resistance) between the p bases in the active region and a cell pitch.

The edge termination structure portion 120 includes, for example, a p-type guard ring 7, a field plate 8, and an insulating film 14 as a film for protecting the termination of the pn junction exposed from the surface 13 of the substrate in order to reduce electric field intensity which is likely to be high when a forward voltage is applied (the collector electrode 11 is connected to a positive electrode and the emitter electrode 9 is connected to a negative electrode) and when a reverse voltage is applied (the collector electrode 11 is connected to the negative electrode and the emitter electrode 9 is connected to the positive electrode). The p-type guard ring 7 is preferably deeper than the p-type base region 2 in order to reduce electric field intensity and is formed at the same time as the termination p base region 2-1. In FIG. 11, reference numeral 2a denotes a p⁺ base contact region.

FIGS. 12 and 13 are cross-sectional views illustrating the structure of a main portion of an IGBT according to the related art. As illustrated in FIG. 12, the IGBT according to the related art has a structure in which a uniform p-type base region 2 is formed by an n-type high-concentration region 15 formed between a p-type base region 2 and an n⁻ drift region 1. The n-type high-concentration region 15 functions as a hole barrier layer which stores holds injected from the p-type collector region to the front surface of the substrate. In addition, the n-type high-concentration region 15 also has a field stop function of suppressing the spreading of a depletion layer when the reverse voltage is applied (for example, JP 2002-532885 W (Abstract and FIG. 1) and JP 2011-155257 A (Abstract and FIG. 1)). JP 2002-532885 W and JP 2011-155257 A also disclose a structure in which an n-type field stop layer 1b is provided in a portion of the n⁻ drift region 1 close to a p-type collector region 10. In the IGBT, the thickness of the n⁻ drift region 1 can be reduced by the n-type high-concentration region 15 provided on the front surface side of the substrate and the n-type field stop layer 1b provided on the rear surface side of the substrate. Therefore, the effect of reducing the on-state voltage is obtained.

In a trench gate IGBT illustrated in FIG. 13, not a reverse blocking IGBT, a structure has been known in which an n-type high-concentration region 16 functions as a hole storage layer (which is synonymous with a hole barrier layer) (for example, see JP 3288218 B1 (paragraph 00062)). In FIGS. 12 and 13, reference numeral 2a denotes a p⁺ base contact region, reference numeral 3 denotes an n⁺ emitter region, reference numeral 4 denotes a gate insulating film, reference numeral 5 denotes a gate electrode, reference numeral 6 denotes an interlayer insulating film, reference numeral 9 denotes an emitter electrode, reference numeral 10 denotes a p-type collector region, and reference numeral 11 denotes a collector electrode.

However, in the reverse blocking IGBT, when the gate is turned off and the reverse voltage is applied, a large amount of reverse leakage current flows. FIG. 14 is a diagram illustrating the reverse leakage current characteristics of the reverse blocking IGBT according to the related art. The left side of FIG. 14 schematically illustrates the cross-sectional structure of a cell region 23 of the active region 110 or a cell region 22 of the termination portion 110a which is surrounded by a dashed line in FIG. 11. The right side of FIG. 14 illustrates an electric field intensity distribution when the reverse voltage is applied. When the reverse voltage (the collector electrode is connected to the negative electrode and the emitter electrode is connected to the positive electrode) is applied, the depletion layer which is spread from the pn junction 10a between the p collector region 10 and the n⁻ drift region 1 to the n⁻ drift region 1 with an increase in the applied voltage expands to a depletion layer region 1-2. As a result, the thickness of the net base region (a region 1-1 which is not depleted) of a pnp transistor which has the p-type base region 2 as the emitter, the n⁻ drift region 1 as the base, and the p collector region 10 as the collector is reduced. In addition, the impurity concentration (doping concentration) of the p-type base region 2 increases and the injection efficiency of the emitter (p-type base region 2) also increases. Therefore, the reverse leakage current generated in the depletion layer region 1-2 (the region which is not depleted) is amplified by the pnp transistor and the amount of reverse leakage current increases. As a result, the operation temperature (heat resistance) of the element is limited.

As disclosed in the above-mentioned JP 10-178174 A, when the n-type high-concentration region la which has a higher concentration than the n⁻ drift region 1 is introduced between the p-type base region 2 and the n⁻ drift region 1, the n-type high-concentration region 1a functions as a field stop layer. However, the n-type high-concentration region 1a becomes a base which has a small width (thickness) in the thickness direction and a small thickness and has high transport efficiency from the viewpoint of the diffusion of holes from the p-type base region 2. Therefore, the n-type high-concentration region 1a does not greatly contribute to reducing the reverse leakage current. It is necessary to further increase the impurity concentration of the n⁻ drift region 1 (the base of the pnp transistor) in order to reduce the gain of the pnp transistor. However, in this case, the forward breakdown voltage of the element is reduced. Therefore, it is difficult to maintain the forward breakdown voltage and to increase the impurity concentration of the n⁻ drift region 1 at the same time.

In order to maintain the large-current turn-off resistance (reverse-biased safe operating area) of the reverse blocking IGBT, it is necessary to provide the emitter electrode 9 so as to be adjacent to the innermost p-type guard ring 7 in the outer circumference of the active region 110, as illustrated in FIG. 11. In general, the p-type guard ring 7 is a few micrometers deeper than the p-type base region 2 in order to reduce electric field intensity when an off-voltage is applied. In this case, as can be seen from FIG. 14, the reverse breakdown voltage is determined by the cell region 22 of the termination portion 110a represented by a dashed line in FIG. 11 and reverse leakage current density per unit surface area is the highest in the cell region 22 of the termination portion 110a. As disclosed in the above-mentioned JP 10-178174 A, when the n-type high-concentration region 1a is provided only in the active region 110, the effect of improving the reverse breakdown voltage is small. In an element with low current capacity, the percentage of the cell region 22 of the termination portion 110a in the entire active region 110 is high and the reverse leakage current reduction effect of the n-type high-concentration region 1a in the cell region 22 of the termination portion 110a is further limited.

The present invention is directed to overcoming or at least reducing the effects of one or more of the problems set forth above.

### SUMMARY OF THE INVENTION

The invention has been made in order to solve the above-mentioned problems of the related art and provides a semiconductor device which can reduce a reverse leakage current, improve a trade-off relationship between an on-state voltage and switching loss, and suppress a peak of spiking collector voltage when the semiconductor device is turned off and a method for producing the semiconductor device.

In order to solve the above-mentioned problems, a semiconductor device according to an aspect of the invention has the following characteristics. A second-conductivity-type base region is provided in one main surface of a first-conductivity-type semiconductor substrate. A first-conductivity-type emitter region is selectively provided in the second-conductivity-type base region. A gate electrode is provided on a surface of a portion of the second-conductivity-type base region interposed between a drift region, which will be the first-conductivity-type semiconductor substrate, and the first-conductivity-type emitter region, with a gate insulating film interposed therebetween. An insulated gate structure including the second-conductivity-type base region, the first-conductivity-type emitter region, and the gate electrode is provided in an active region. A edge termination structure portion is provided so as to surround the outer circumference of the active region. A second-conductivity-type collector layer is provided in the other main surface of the first-conductivity-type semiconductor substrate. A second-conductivity-type isolation layer is provided in an outer circumferential portion of the edge termination structure portion so as to pass through the first-conductivity-type semiconductor substrate in a depth direction. The second-conductivity-type isolation layer is electrically connected to the second-conductivity-type collector layer. A first-conductivity-type high-concentration region is provided in the one main surface of the first-conductivity-type semiconductor substrate at a depth of 20 μm or less from a bottom of the second-conductivity-type base region to the second-conductivity-type collector layer. A ratio of the impurity concentration n₁ of the first-conductivity-type high-concentration region to the impurity concentration n₂ of the drift region satisfies 1.0<n₁/n₂≦5.0.

In the semiconductor device according to the above-mentioned aspect of the invention, the depth of the second-conductivity-type base region in the outermost circumference of the active region may be more than the depth of the second-conductivity-type base region which is disposed inside the outermost second-conductivity-type base region.

In the semiconductor device according to the above-mentioned aspect of the invention, the depth of the second-conductivity-type base region in the outermost circumference of the active region may be equal to the depth of a second-conductivity-type guard ring forming the edge termination structure portion.

According to another aspect of the invention, a method for producing the semiconductor device according to the above-mentioned aspect of the invention has the following characteristics. A first thermal diffusion step performs thermal diffusion for a thermal diffusion time, which is obtained by subtracting a thermal diffusion time required to diffuse the first-conductivity-type high-concentration region to a predetermined depth from a full diffusion time required to diffuse the second-conductivity-type isolation layer for obtaining a predetermined design breakdown voltage to a final depth, to form the second-conductivity-type isolation layer at a depth that is less than the final diffusion depth of the second-conductivity-type isolation layer. Then, after the first thermal diffusion step, a second thermal diffusion step performs thermal diffusion for a thermal diffusion time required to diffuse the first-conductivity-type high-concentration region to the predetermined depth to diffuse the first-conductivity-type high-concentration region to the predetermined depth, and at the same time, the second thermal diffusion step completes diffusing the second-conductivity-type isolation layer to the final depth.

In the method for producing the semiconductor device according to the above-mentioned aspect of the invention, an implantation step of implanting first-conductivity-type impurity ions into the entire one main surface of the first-conductivity-type semiconductor substrate to form the first-conductivity-type high-concentration region may be performed after the first thermal diffusion step and before the second thermal diffusion step. In the implantation step, the impurity ions may be phosphorus ions and an implantation dose may be in the range of 0.6×10¹² cm⁻² to 1.2×10¹² cm⁻². In the second thermal diffusion step, a thermal diffusion temperature may be in the range of 1250° C. to 1350° C. and a thermal diffusion time may be in the range of 30 hours to 60 hours.

According to the semiconductor device and the semiconductor device producing method of the invention, it is possible to reduce a high-temperature reverse leakage current when the reverse voltage is applied, to improve the trade-off relationship between turn-off loss (Eoff) and the on-state voltage (Von), and to reduce the rising peak voltage of the collector voltage when the semiconductor device is turned off. As a result, it is possible to improve the overheat resistance and overvoltage resistance of the semiconductor device.

### BRIEF DESCRIPTION OF THE DRAWINGS

The foregoing advantages and features of the invention will become apparent upon reference to the following detailed description and the accompanying drawings, of which:

FIG. 1 is a cross-sectional view illustrating the structure of a main portion of a reverse blocking IGBT according to an embodiment of the invention;

FIGS. 2A and 2B are characteristic diagrams illustrating the profiles of the impurity concentration (doping concentration) (A) and lifetime (B) of the reverse blocking IGBT according to the embodiment of the invention;

FIG. 3 is a characteristic diagram illustrating the relationship among a reverse leakage current at a junction temperature T of 125° C., the forward and reverse breakdown voltages at room temperature, and a doping concentration ratio n₁/n₂ in a termination portion of an active region in the reverse blocking IGBT according to the embodiment of the invention;

FIG. 4 is a characteristic diagram illustrating the relationship between the turn-off loss (Eoff) and on-state voltage (Von) of the reverse blocking IGBT according to the embodiment of the invention;

FIG. 5 is a characteristic diagram illustrating the relationship between the on-state voltage (Von) and the value of dV/dt when the reverse blocking IGBT according to the embodiment of the invention is turned off;

FIG. 6 is a characteristic diagram illustrating the relationship between the on-state voltage (Von) and the rise of a collector voltage when the reverse blocking IGBT according to the embodiment of the invention is turned off;

FIG. 7 is a cross-sectional view illustrating the state of the reverse blocking IGBT according to the embodiment of the invention which is being produced (part 1);

FIG. 8 is a cross-sectional view illustrating the state of the reverse blocking IGBT according to the embodiment of the invention which is being produced (part 2);

FIG. 9 is a cross-sectional view illustrating the state of the reverse blocking IGBT according to the embodiment of the invention which is being produced (part 3);

FIG. 10 is a cross-sectional view illustrating the state of the reverse blocking IGBT according to the embodiment of the invention which is being produced (part 4);

FIG. 11 is a cross-sectional view illustrating the structure of a main portion of a reverse blocking IGBT according to the related art;

FIG. 12 is a cross-sectional view illustrating the structure of a main portion of an IGBT according to the related art;

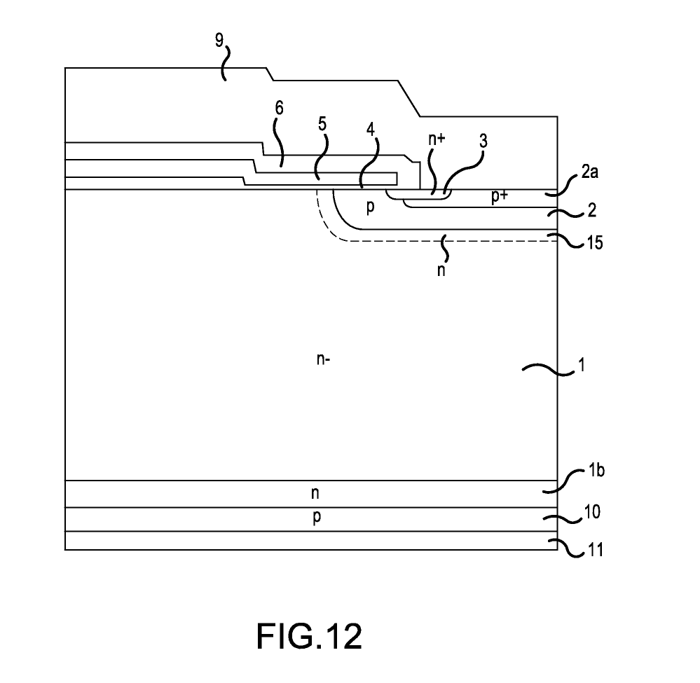

FIG. 13 is a cross-sectional view illustrating the structure of the main portion of the IGBT according to the related art; and

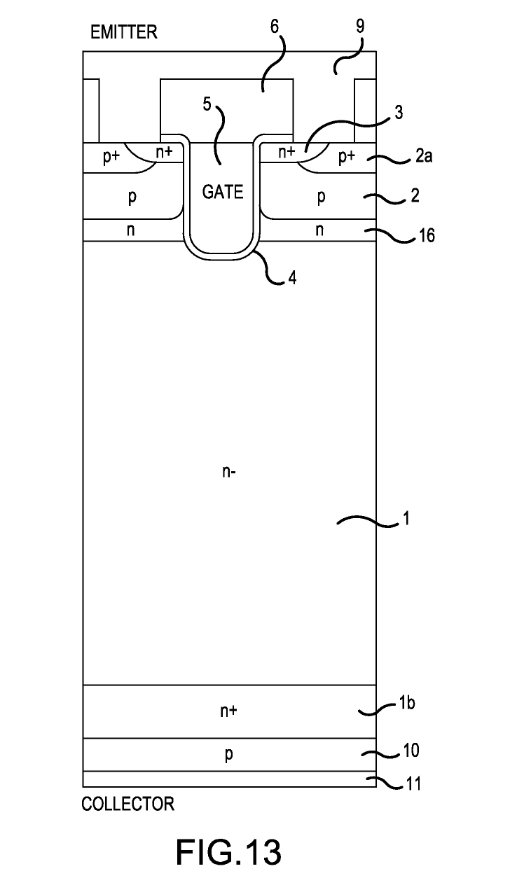

FIG. 14 is a diagram illustrating the reverse leakage current characteristics of the reverse blocking IGBT according to the related art.

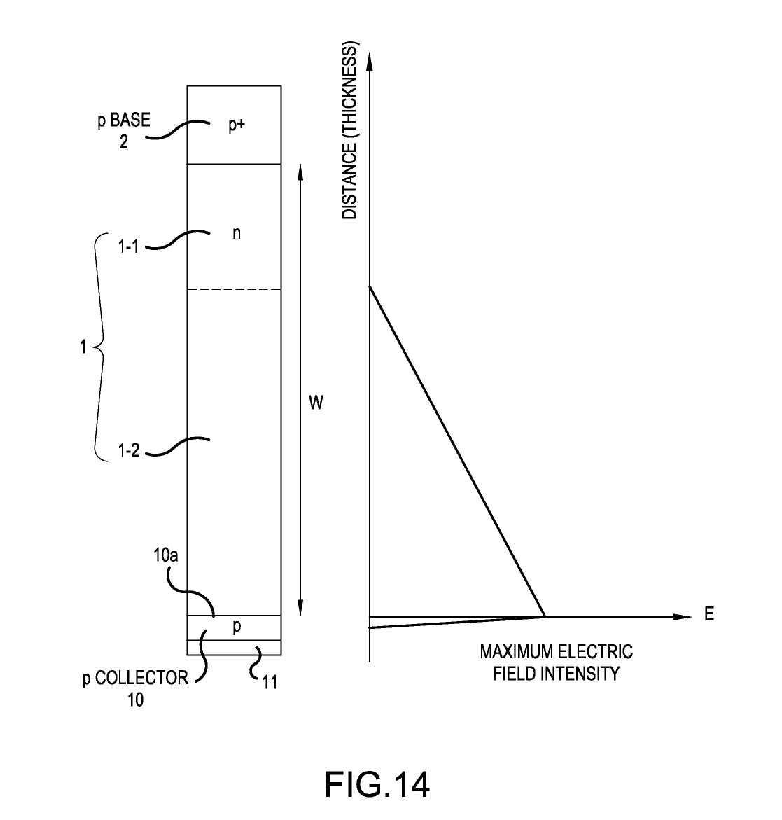

### DETAILED DESCRIPTION OF SPECIFIC EMBODIMENTS

Hereinafter, preferred embodiments of a semiconductor device and a semiconductor device producing method according to the invention will be described in detail with reference to the specification and the accompanying drawings. In the specification and the accompanying drawings, in the layers or regions having “n” or “p” appended thereto, an electron or a hole means a major carrier. In addition, symbols “+” and “−” added to n or p mean that impurity concentration is higher and lower than that of the layer without the symbols. In the description of the following embodiments and the accompanying drawings, the same components are denoted by the same reference numerals and the description thereof will not be repeated. In addition, in the accompanying drawings described in the embodiments, for ease of viewing or understanding, a scale and a dimensional ratio are different from the actual scale and dimensional ratio. The invention is not limited to the following embodiments as long as it does not depart from the scope and spirit thereof.

### Embodiment

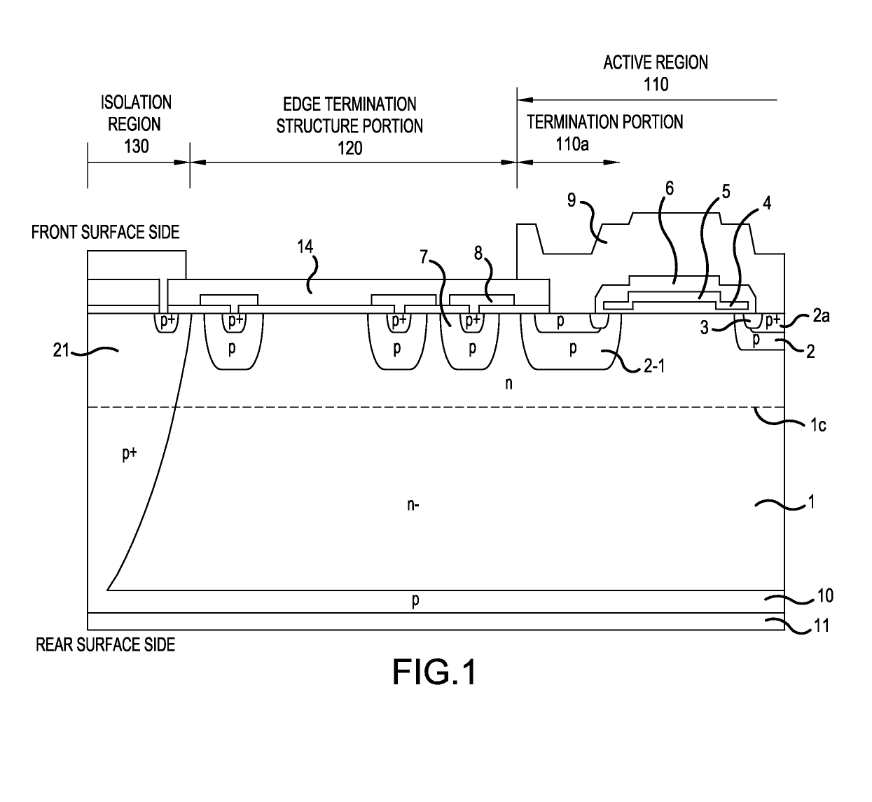

A reverse blocking IGBT will be described as an example of a reverse blocking semiconductor device according to an embodiment of the invention. FIG. 1 is a cross-sectional view illustrating the structure of a main portion of the reverse blocking IGBT according to the embodiment of the invention. As illustrated in FIG. 1, the reverse blocking IGBT according to the embodiment includes an active region 110 which is provided in the vicinity of the center of a chip, an edge termination structure portion 120 which is provided in the outer circumference surrounding the active region 110, and a isolation region 130 which surrounds the outside of the edge termination structure portion 120. The isolation region 130 includes, as a main region, a p⁺ isolation layer 21 for connecting one main surface and the other main surface of an n⁻ semiconductor substrate with a p-type region. That is, the p⁺ isolation layer 21 is provided so as to pass through the n⁻ semiconductor substrate in a depth direction.

The p⁺ isolation layer 21 is formed by the thermal diffusion of impurities (for example, boron) from the one main surface of the n⁻ semiconductor substrate. The p⁺ isolation layer 21 is provided so as to come into contact with a p-type collector region 10. The p⁺ isolation layer 21 prevents the termination of a pn junction surface between the p-type collector region 10 and an n⁻ drift region 1, which is a reverse breakdown voltage junction, from being exposed from the side end surface of the chip which is a cut surface during chipping. In addition, the p⁺ isolation layer 21 causes the pn junction surface between the p-type collector region 10 and the n⁻ drift region 1 to be exposed from the surface of the substrate (the front surface of the substrate) protected by an insulating film 14 in the edge termination structure portion 120. Therefore, it is possible to improve the reliability of a reverse breakdown voltage.

In the active region 110, a front-surface-side structure including, for example, the n⁻ drift region 1, a p-type base region 2, a p⁺ base contact region 2a, an n⁺ emitter region 3, a gate insulating film 4, a gate electrode 5, an interlayer insulating film 6, and an emitter electrode 9 is provided on the front surface side of the n⁻ semiconductor substrate. A rear surface structure including, for example, the p-type collector region 10 and a collector electrode 11 is provided on the rear surface side of the n⁻ semiconductor substrate. The active region 110 is a main current path of a vertical IGBT. The depth of an outermost p base region (hereinafter, referred to as a termination p base region) 2-1 which is provided in a termination portion 110a of the active region 110 close to the edge termination structure portion 120 is more than the depth of the p-type base region 2 provided inside the termination p base region 2-1.

In the edge termination structure portion 120, for example, a p-type guard ring 7, a field plate 8, and the insulating film 14 are provided on the front surface side of the n⁻ semiconductor substrate. The edge termination structure portion 120 reduces the electric field of a portion of the n⁻ drift region 1 close to the front surface of the substrate and holds the breakdown voltage. Specifically, the edge termination structure portion 120 has a function of reducing electric field intensity which is likely to be high when a forward voltage is applied (the collector electrode 11 is connected to a positive electrode and the emitter electrode 9 is connected to a negative electrode) and when a reverse voltage is applied (the collector electrode 11 is connected to the negative electrode and the emitter electrode 9 is connected to the positive electrode). An n-type high-concentration region 1c is provided in a surface layer of the n⁻ drift region 1 close to the front surface of the substrate so as to extend from the active region 110 to the edge termination structure portion 120. The depth of the n-type high-concentration region 1c is more than that of the termination p base region 2-1 and the p-type guard ring 7.

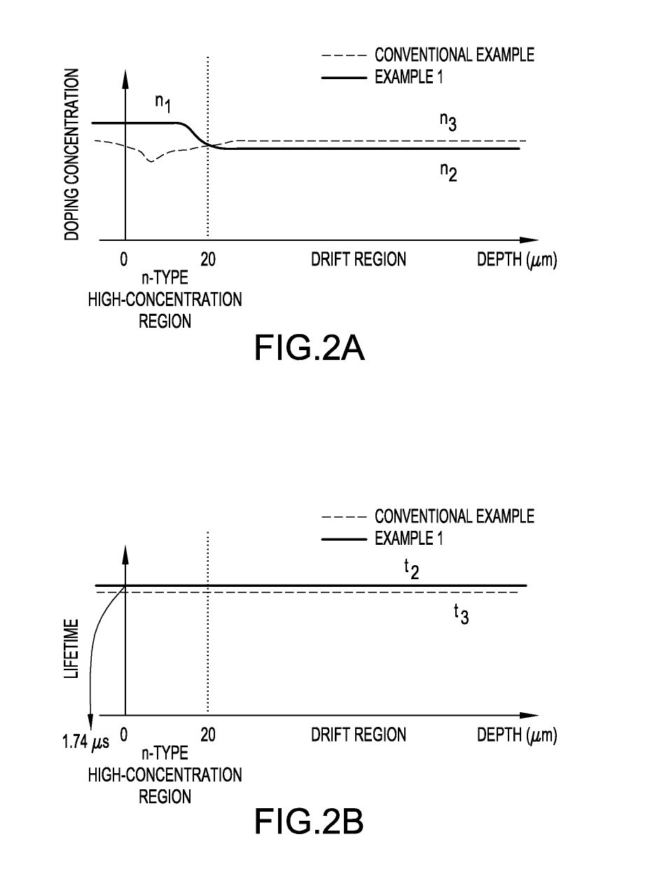

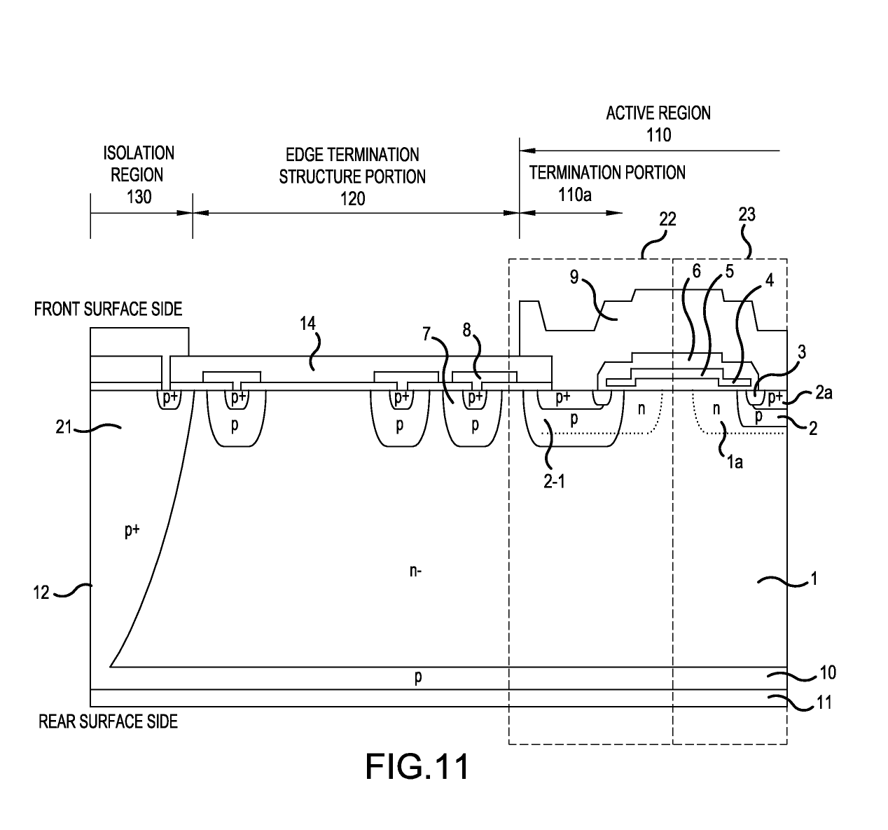

Next, the profiles of the impurity concentration (doping concentration) and lifetime of the reverse blocking IGBT according to the embodiment will be described. FIG. 2 is a characteristic diagram illustrating the profiles of the impurity concentration (doping concentration) (A) and lifetime (B) of the reverse blocking IGBT according to the embodiment of the invention. FIG. 2A is a diagram illustrating the comparison between the profile of the doping concentration of the reverse blocking IGBT according to the embodiment illustrated in FIG. 1 (hereinafter, referred to as Example 1) and the profile of the doping concentration of the reverse blocking IGBT according to the related art illustrated in FIG. 11 and FIG. 2B is a diagram illustrating the comparison between the profiles of the carrier lifetimes (hereinafter, simply referred to as lifetime) thereof.

In FIGS. 2A and 2B, the vertical axes indicate the doping concentration and the lifetime, respectively. In FIGS. 2A and 2B, the horizontal axis indicates the distance in the depth direction. The position of the origin 0 on the horizontal axis indicates the bottom of the p-type guard ring 7 in the edge termination structure portion 120 or the bottom of the termination p base region 2-1 in the termination portion 110a of the active region 110 in the reverse blocking IGBT. The position of a dotted line indicating 20 μm on the horizontal axis is an example of the depth of the n-type high-concentration region 1c from the bottom of the termination p base region 2-1 in the reverse blocking IGBT according to Example 1. It is preferable that the n-type high-concentration region 1c be deeper than the bottom of the termination p base region 2-1 and have a depth of 20 μm or less. The reason is that, when the depth of the n-type high-concentration region 1c is greater than 20 μm, the effect of storing holes in the front surface of an element is reduced and an on-state voltage (Von) significantly increases, which is not preferable.

In the reverse blocking IGBT (FIG. 1) according to the embodiment of the invention, it is preferable that the doping concentration n₁ of the n-type high-concentration region 1c which is provided at a depth of 20 μm or less from the bottom of the termination p base region 2-1 be equal to or less than five times the doping concentration n₂ of the n⁻ drift region 1 (doping concentration ratio n₁/n₂=5.0). The reason will be described below.

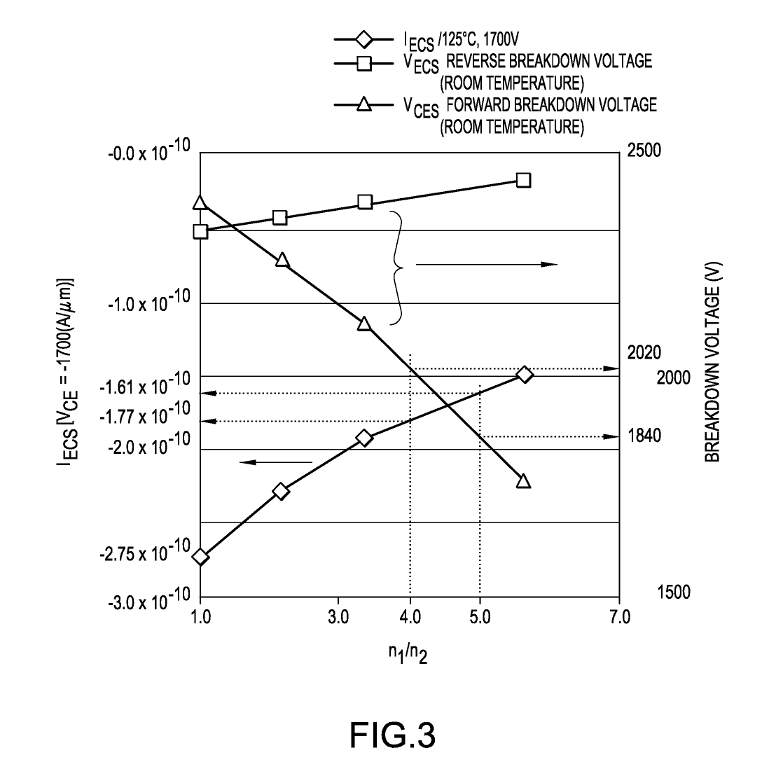

FIG. 3 is a characteristic diagram illustrating the relationship among a reverse leakage current at a junction temperature T of 125° C., the forward and reverse breakdown voltages at room temperature, and the doping concentration ratio n₁/n₂ in the termination portion of the active region in the reverse blocking IGBT according to the embodiment of the invention. FIG. 3 illustrates the simulation result of the dependence of the forward breakdown voltage at room temperature (for example, 25° C.) (hereinafter, referred to as a room-temperature forward breakdown voltage) (Δ mark), the reverse breakdown voltage at room temperature (hereinafter, referred to as a room temperature reverse breakdown voltage) (□ mark), and a reverse leakage current IECS at a junction temperature T of 125° C. and a reverse breakdown voltage VECS of 1700 V (hereinafter, referred to as a high-temperature reverse leakage current) (⋄ mark) in the termination portion 110a of the active region 110 of the reverse blocking IGBT with a design breakdown voltage of 1700 V on the doping concentration ratio n₁/n₂. However, the lifetime t₂ of the reverse blocking IGBT according to Example 1 was 1.74 μs which was equal to the lifetime t₃ of the reverse blocking IGBT according to the related art.

As can be seen from the result illustrated in FIG. 3, when the doping concentration ratio n₁/n₂ is in the range of 4.0 to 5.0, the room-temperature forward breakdown voltage (⋄ mark) is in the range of about 1840 V to 2020 V. Therefore, it is possible to ensure a forward breakdown voltage of about 1800 V or more. However, when the doping concentration ratio n₁/n₂ is greater than 5.0, the forward breakdown voltage is further reduced and it is difficult to ensure a design breakdown voltage of 1700 V, which is not preferable.

As can be seen from the result illustrated in FIG. 3, when the doping concentration ratio n₁/n₂ is in the range of 4.0 to 5.0, the high-temperature reverse leakage current (⋄ mark) at a junction temperature T of 125° C. is reduced from 2.75×10⁻¹⁰ (A/μm), which is the reverse leakage current value in the reverse blocking IGBT (doping concentration ratio n₁/n₂=1.0) according to the related art, to the range of 1.77×10⁻¹⁰ (A/μm) to 1.61×10⁻¹⁰ (A/μm). Therefore, in the reverse blocking IGBT according to Example 1, the high-temperature reverse leakage current is reduced to about 70% of the high-temperature reverse leakage current of the reverse blocking IGBT according to the related art. The leakage current at a high temperature is reduced when the doping concentration ratio n₁/n₂ is greater than 1.0.

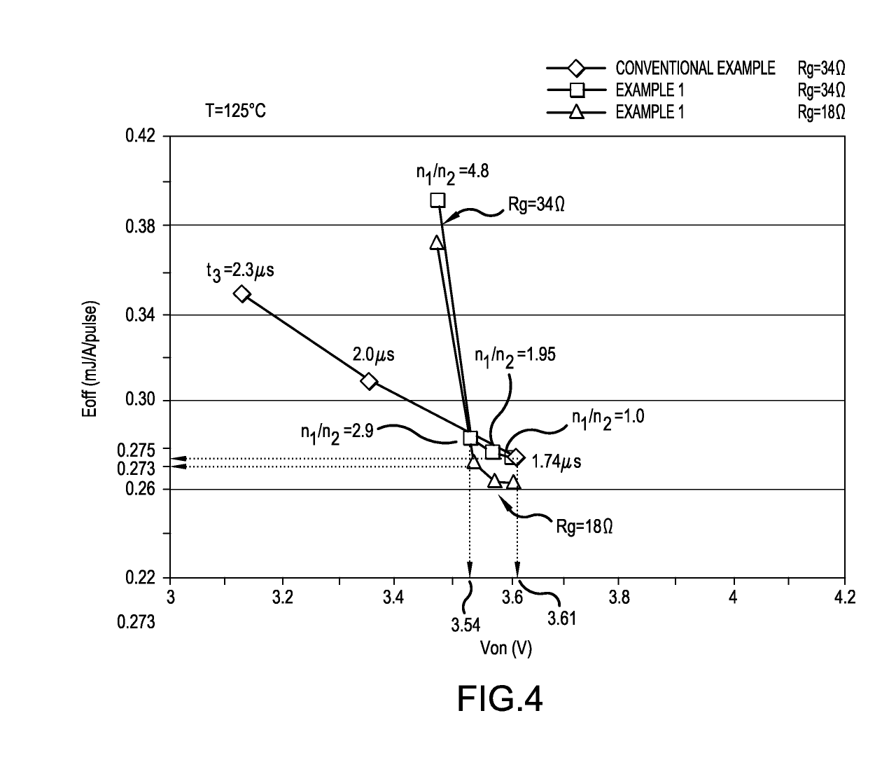

FIG. 4 is a characteristic diagram illustrating the relationship between the turn-off loss (Eoff) and on-state voltage (Von) of the reverse blocking IGBT according to the embodiment of the invention. FIG. 4 illustrates the trade-off relationship between the turn-off loss (Eoff) and the on-state voltage (Von) of the reverse blocking IGBT according to Example 1 and the reverse blocking IGBT according to the related art. In the reverse blocking IGBT according to Example 1 and the reverse blocking IGBT according to the related art, collector injection conditions were constant. The result of the reverse blocking IGBT according to the related art illustrated in FIG. 4 is obtained by changing the lifetime t₃ and the doping concentration ratio n₁/n₂. In contrast, the result of the reverse blocking IGBT according to Example 1 illustrated in FIG. 4 is obtained by changing the doping concentration ratio n₁/n₂, with the lifetime t₂ fixed to 1.74 μs.

Specifically, the lifetime t₃ of the reverse blocking IGBT (⋄ mark) according to the related art was 2.3 μs, 2.0 μs, and 1.74 μs at each data point which was disposed from the upper left side to the lower right side of the characteristic curve. Both two reverse blocking IGBTs (□ and ⋄ marks) with different gate resistance values according to Example 1, the doping concentration ratio n₁/n₂ was 4.8, 2.9, 1.95, and 1.0 at each data point which was disposed from the upper left side to the lower right side of the characteristic curve. The turn-off gate resistance Rg of the reverse blocking IGBT (⋄ mark) according to the related art was 34Ω and the turn-off gate resistance values Rg of two reverse blocking IGBTs according to Example 1 were 34Ω (□ mark) and 18Ω (Δ mark).

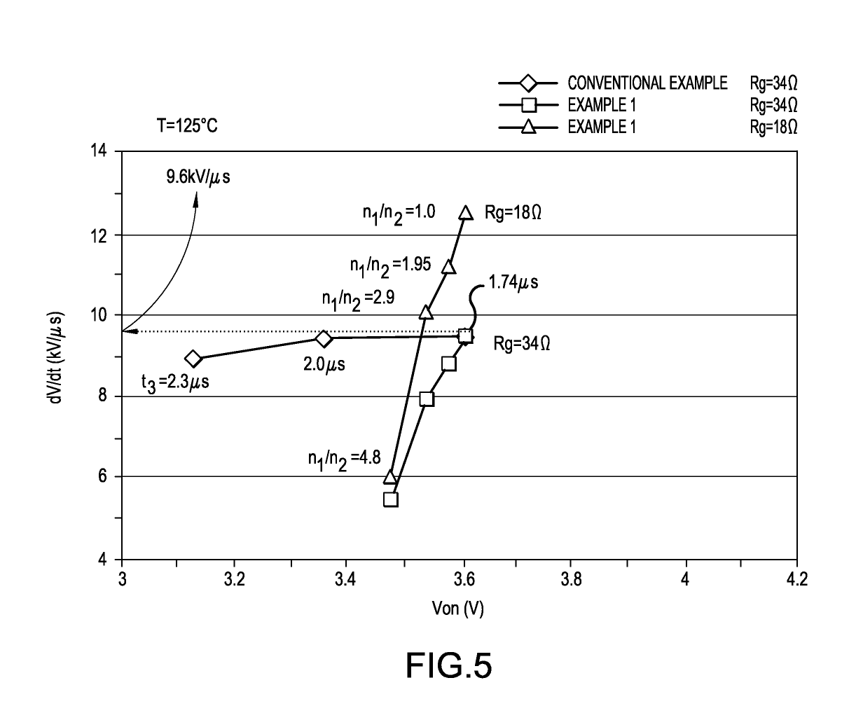

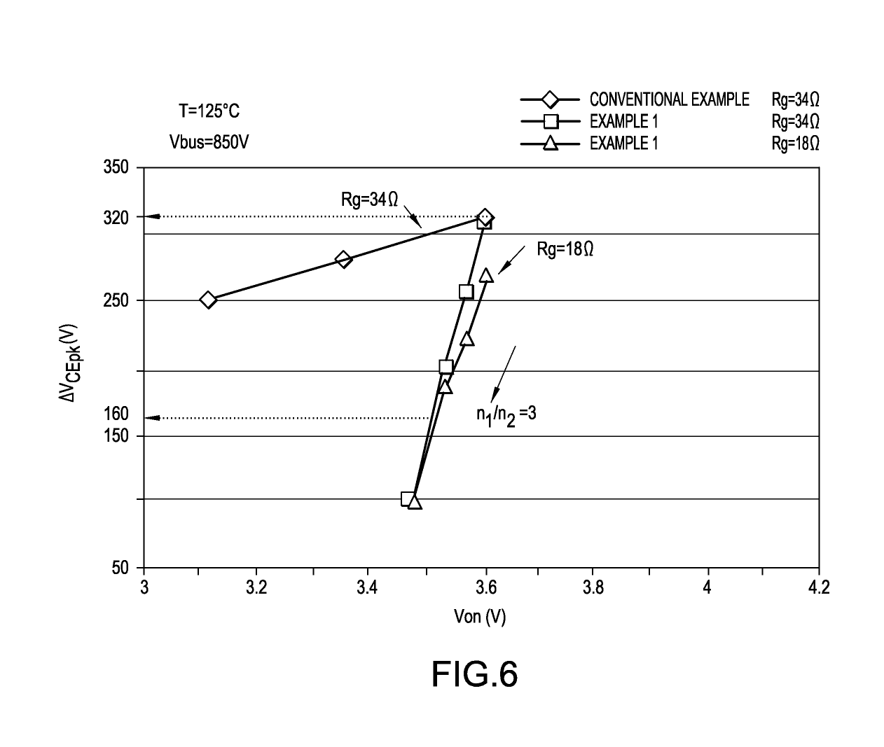

FIG. 5 illustrates the value of dV/dt (the rising gradient of the reverse voltage) of each reverse blocking IGBT at the same data points as those illustrated in FIG. 4. The bus voltage Vbus of a switching-off test circuit was 850 V. Parasitic inductance was 300 nH. FIG. 6 illustrates a rising peak voltage ΔVCEpk=(VCEpk−850 V) of the collector voltage of each reverse blocking IGBT under the same conditions as those illustrated in FIG. 4. FIG. 5 is a characteristic diagram illustrating the relationship between the on-state voltage (Von) and the value of dV/dt when the reverse blocking IGBT according to the embodiment of the invention is turned off. FIG. 6 is a characteristic diagram illustrating the relationship between the on-state voltage (Von) and the rise of the collector voltage when the reverse blocking IGBT according to the embodiment of the invention is turned off.

As can be seen from FIG. 5, under the same carrier lifetime condition (for example, a lifetime t is 1.74 μs), the reverse blocking IGBT (⋄ mark) according to the related art when the turn-off gate resistance Rg is 34Ω and the reverse blocking IGBT (Δ mark) according to Example 1 when the doping concentration ratio n₁/n₂ is approximately 3.0 and the turn-off gate resistance Rg is 18Ω have similar dV/dt (9.6 kV/μs). In the reverse blocking IGBTs (Δ and □ marks) according to Example 1, when the doping concentration ratio n₁/n₂ increases, the value of dV/dt (the rising gradient of the reverse voltage) is reduced. At the same level of dV/dt, the reverse blocking IGBT (Δ mark) according to Example 1 when the turn-off gate resistance Rg is 18Ω can perform switching with small turn-off gate resistance (Rg=18Ω), as compared to the reverse blocking IGBT (⋄ mark) according to the related art, and the turn-off loss Eoff is reduced. Therefore, the reverse blocking IGBT according to the invention can reduce the on-state voltage Von at the same level of Eoff or dV/dt.

Similarly, as can be seen from FIG. 4, the turn-off loss Eoff and the on-state voltage Von of the reverse blocking IGBT (⋄ mark) according to the related art at a lifetime t₃ of 1.74 μs are 0.275 mJ/A/pulse and 3.61 V, respectively. In contrast, the turn-off loss Eoff and the on-state voltage Von of the reverse blocking IGBT (⋄ mark) according to Example 1 when the doping concentration ratio n₁/n₂ is approximately 3.0 and the turn-off gate resistance Rg is 18Ω are 0.273 mJ/A/pulse and 3.54 V, respectively. Therefore, in the reverse blocking IGBT according to Example 1, when the rising gradient (dV/dt) of the collector voltage at the time of turn-off is similar (9.6 kV/μs) to that in the reverse blocking IGBT according to the related art, the on-state voltage is lower than that in the reverse blocking IGBT according to the related art, which is preferable.

As illustrated in FIG. 6, in the reverse blocking IGBT (⋄ mark) according to Example 1 when the turn-off gate resistance Rg is 18Ω, when the doping concentration ratio n₁/n₂ is 3, the rising peak voltage ΔVCEpk of the collector voltage is 160 V. In contrast, in the reverse blocking IGBT (⋄ mark) according to the related art, the rising peak voltage ΔVCEpk of the collector voltage is 320 V. As such, in the reverse blocking IGBT (⋄ mark) according to Example 1 when the turn-off gate resistance Rg is 18Ω, when the doping concentration ratio n₁/n₂ is 3, the rising peak voltage ΔVCEpk of the collector voltage is about half the rising peak voltage ΔVCEpk of the collector voltage in the reverse blocking IGBT (⋄ mark) according to the related art. Therefore, the reverse blocking IGBT (⋄ mark) according to Example 1 when the turn-off gate resistance Rg is 18⋄ has a higher overvoltage resistance than the reverse blocking IGBT (⋄ mark) according to the related art.

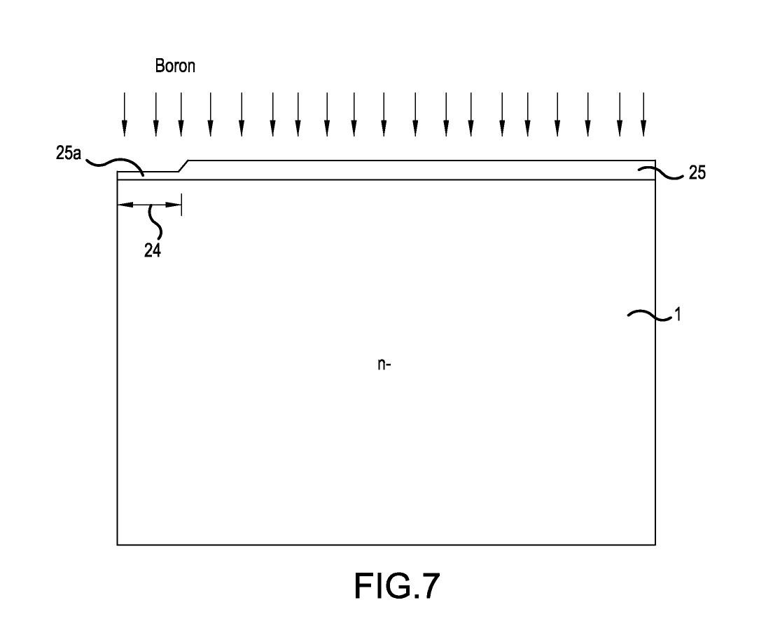

Next, as an example of a method for producing the reverse blocking semiconductor device according to the embodiment, a method for producing (producing) a reverse blocking IGBT and a method for forming the n-type high-concentration region 1c will be mainly described. FIGS. 7 to 10 are cross-sectional views illustrating the reverse blocking IGBT according to the embodiment of the invention which is being produced. First, as illustrated in FIG. 7, a thermally-oxidized film 25 is formed on the front surface of an n-type FZ silicon semiconductor substrate (hereinafter, referred to as a semiconductor substrate) which will be the n⁻ drift region 1. A portion of the thermally-oxidized film 25 is etched, using a photoresist (not illustrated) formed in a photolithography step as a mask, to form an opening portion 24 through which a portion of the semiconductor substrate corresponding to a region for forming the p⁺ isolation layer 21 is exposed.

The photoresist is removed and the semiconductor substrate is cleaned. A screen oxide film 25a which is thinner than the thermally-oxidized film 25 is formed on a portion of the front surface of the substrate which is exposed through the opening portion 24 of the thermally-oxidized film 25 by thermal oxidation. Then, for example, boron (B) ions are implanted into the entire front surface of the semiconductor substrate. The ion implantation is performed under the conditions of, for example, a dose of 5×10¹⁵ cm⁻² and an implantation energy of 45 KeV. The thickness of the thermally-oxidized film 25 and the screen oxide film 25a is selected such that the boron ions are implanted into the semiconductor substrate only from the screen oxide film 25a in the opening portion 24 and a portion of the semiconductor substrate below the thermally-oxidized film 25 functions as a mask.

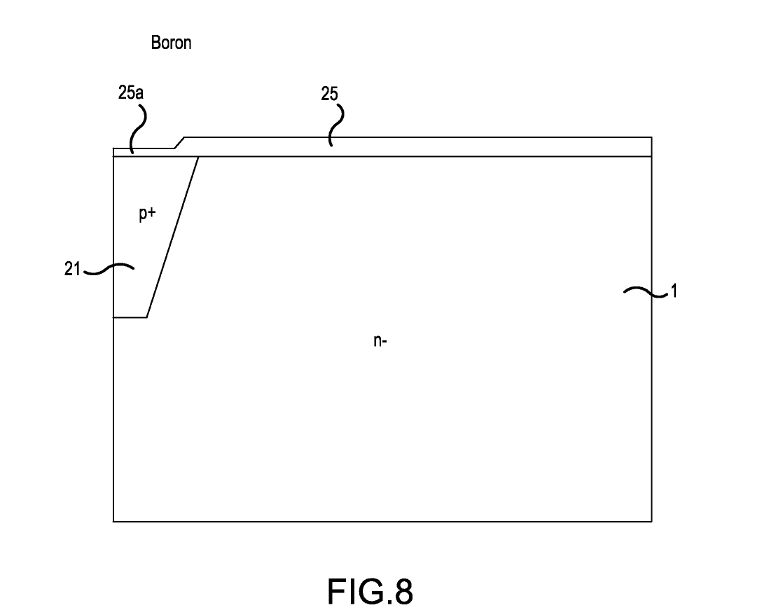

As illustrated in FIG. 8, a general p⁺ isolation layer diffusion step is performed and the p⁺ isolation layer 21 is formed by the thermal diffusion of boron. The diffusion is performed in, for example, an argon (Ar) atmosphere or a nitrogen (N₂) atmosphere including oxygen (O₂). The diffusion temperature is in the range of, for example, 1250° C. to 1350° C. The diffusion time depends on the final depth of the p⁺ isolation layer 21 which is determined by the diffusion temperature and the design breakdown voltage. The final depth means the design thickness of a semiconductor region or a semiconductor layer in the completed reverse blocking IGBT. In the reverse blocking IGBT according to the invention, the diffusion time is about 30 hours to 60 hours shorter than the full diffusion time required to form the p⁺ isolation layer 21 for achieving a reverse blocking IGBT with a predetermined design breakdown voltage in this processing stage and the diffusion depth of the p⁺ isolation layer 21 is reduced by a value corresponding to the reduced diffusion time.

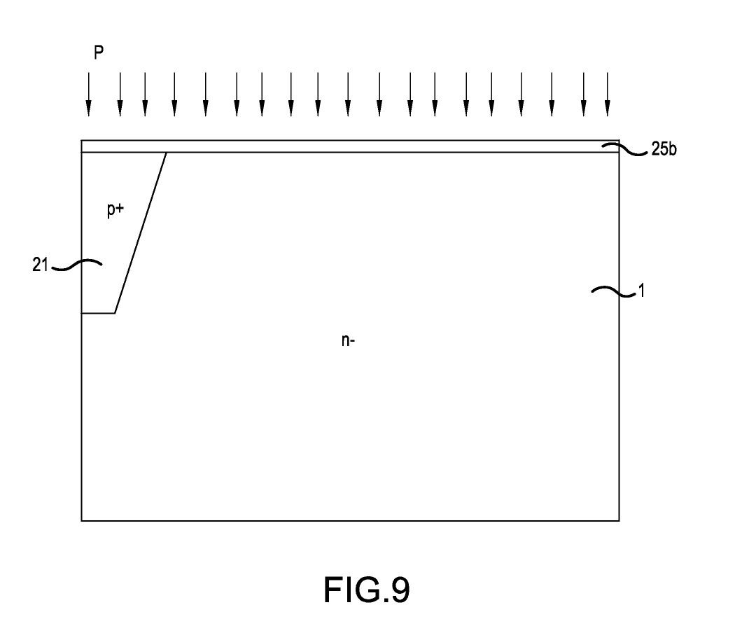

As illustrated in FIG. 9, the thermally-oxidized film 25 is removed from the entire surface of the semiconductor substrate. A screen oxide film 25b is formed with a thickness of about 30 nm to 100 nm on the entire front surface of the semiconductor substrate by thermal oxidation. Then, for example, phosphorus (P) ions are implanted into the entire front surface of the semiconductor substrate through the screen oxide film 25b. The ion implantation is performed under the conditions of, for example, an implantation energy of 100 KeV to 300 KeV and a dose of 0.6×10¹² cm⁻² to 1.2×10¹² cm⁻². Then, the screen oxide film 25b is removed from the entire front surface of the semiconductor substrate. Then, an oxide film (not illustrated) with a thickness of 0.2 μm to 0.4 μm is deposited on the surface of the semiconductor substrate by a CVD method.

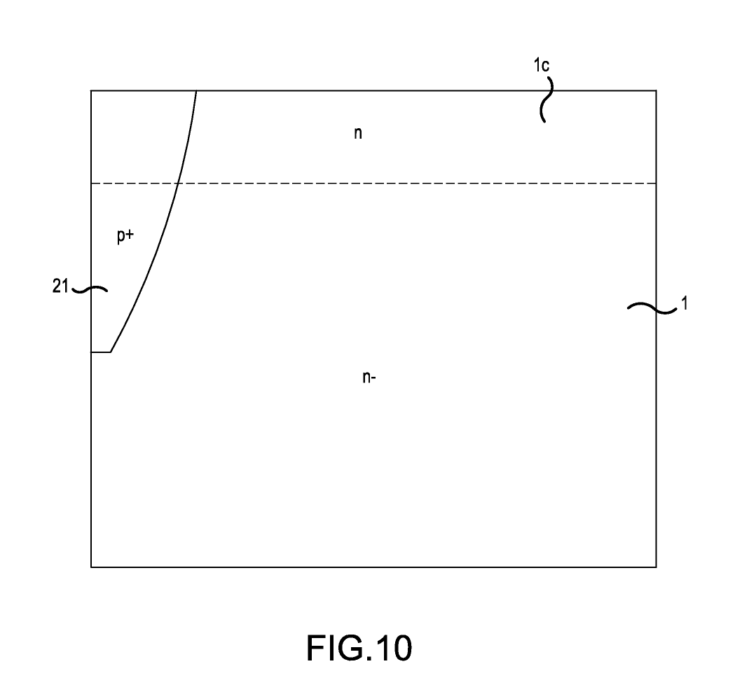

As illustrated in FIG. 10, thermal diffusion is additionally performed for 30 hours to 60 hours, which are the shortage of the diffusion time of the p⁺ isolation layer 21 required to obtain a predetermined design breakdown voltage, under the same thermal diffusion temperature conditions as those in the method for forming the p⁺ isolation layer 21 which has been described with reference to FIG. 8. In this way, the n-type high-concentration region 1c is formed in the surface layer of the front surface of the semiconductor substrate at a predetermined diffusion depth by the thermal diffusion of phosphorus and the p⁺ isolation layer 21 is diffused. As a result, the p⁺ isolation layer 21 has a diffusion depth required to obtain the breakdown voltage. The oxide film is removed from the entire surface of the semiconductor substrate. Then, the production process which has been well known in the reverse blocking IGBT according to the related art is performed to complete the reverse blocking IGBT according to the invention illustrated in FIG. 1.

As described above, according to the invention, the n-type high-concentration region is formed in the surface layer of the front surface of the semiconductor substrate at a depth of 20 μm or less from the bottom of the p-type base region such that the doping concentration ratio n₁/n₂ is greater than 1.0 and equal to or less than 5.0. According to this structure, it is possible to reduce the high-temperature reverse leakage current and the rising peak voltage of the collector voltage at the time of turn-off, without significantly reducing the forward breakdown voltage, while improving the trade-off relationship between the turn-off loss (Eoff) and the on-state voltage (Von). Therefore, it is possible to widen the range of the operation temperature or to reduce the volume of a heat sink. As a result, the reverse blocking IGBT can operate at a high temperature or the size of the reverse blocking IGBT can be reduced. The application range of a matrix converter or a multi-level inverter provided with the reverse blocking IGBT is widened and the energy conversion efficiency of industrial or consumer equipment is improved.

The invention is not limited to the above-described embodiment, but various modifications and changes of the invention can be made without departing from the scope and spirit of the invention.

As described above, the semiconductor device and the semiconductor device producing method according to the invention are useful for a power semiconductor device that is used in a power conversion device, such as an inverter, or industrial or consumer equipment.

Thus, a semiconductor device and method for its manufacture have been described according to the present invention. Many modifications and variations may be made to the techniques and structures described and illustrated herein without departing from the spirit and scope of the invention. Accordingly, it should be understood that the methods and devices described herein are illustrative only and are not limiting upon the scope of the invention.

### EXPLANATIONS OF LETTERS OR NUMERALS

1 n⁻ drift region

1c n-type high-concentration region

2 p-type base region

2a p⁺ base contact region

2-1 termination p base region

3 n⁺ emitter region

4 gate insulating film

5 gate electrode

6 interlayer insulating film

7 p-type guard ring

8 field plate

9 emitter electrode

10 p-type collector region

10a pn junction between p-type collector region and n⁻ drift region

11 collector electrode

12 side end surface of chip

13 surface of substrate

14 insulating film

21 p⁺ isolation layer

23 cell region

24 opening portion of thermally-oxidized film

25 thermally-oxidized film

25a screen oxide film

110 active region

110a termination portion

120 edge termination structure portion

130 isolation region

What is claimed is:

1. A semiconductor device comprising:
an active region that is provided with an insulated gate structure including a second-conductivity-type base region which is provided in one main surface of a first-conductivity-type semiconductor substrate, a first-conductivity-type emitter region which is selectively provided in the second-conductivity-type base region, and a gate electrode which is provided on a surface of a portion of the second-conductivity-type base region interposed between a drift region, which will be the first-conductivity-type semiconductor substrate, and the first-conductivity-type emitter region, with a gate insulating film interposed therebetween;
an edge termination structure portion that surrounds the outer circumference of the active region;
a second-conductivity-type collector layer that is provided on the other main surface of the first-conductivity-type semiconductor substrate;
a second-conductivity-type isolation layer that is provided in an outer circumferential portion of the edge termination structure portion, passes through the first-conductivity-type semiconductor substrate in a depth direction, and is electrically connected to the second-conductivity-type collector layer; and
a first-conductivity-type high-concentration region that is provided from the one main surface of the first-conductivity-type semiconductor substrate within a depth of 20 μm or less from a bottom of the second-conductivity-type base region towards the second-conductivity-type collector layer,
wherein a ratio of the impurity concentration n₁ of the first-conductivity-type high-concentration region to the impurity concentration n₂ of the drift region satisfies 1.0<n₁/n₂≦5.0.

2. The semiconductor device according to claim 1, wherein the depth of the second-conductivity-type base region in the outermost circumference of the active region is more than the depth of the second-conductivity-type base region which is disposed inside the outermost second-conductivity-type base region.

3. The semiconductor device according to claim 1, wherein the depth of the second-conductivity-type base region in the outermost circumference of the active region is equal to the depth of a second-conductivity-type guard ring forming the edge termination structure portion.

4. The semiconductor device according to claim 2, wherein the depth of the second-conductivity-type base region in the outermost circumference of the active region is equal to the depth of a second-conductivity-type guard ring forming the edge termination structure portion.

5. A method for producing the semiconductor device comprising:
an active region that is provided with an insulated gate structure including a second-conductivity-type base region which is provided in one main surface of a first-conductivity-type semiconductor substrate, a first-conductivity-type emitter region which is selectively provided in the second-conductivity-type base region, and a gate electrode which is provided on a surface of a portion of the second-conductivity-type base region interposed between a drift region, which will be the first-conductivity-type semiconductor substrate, and the first-conductivity-type emitter region, with a gate insulating film interposed therebetween;
an edge termination structure portion that surrounds the outer circumference of the active region;
a second-conductivity-type collector layer that is provided on the other main surface of the first-conductivity-type semiconductor substrate;
a second-conductivity-type isolation layer that is provided in an outer circumferential portion of the edge termination structure portion, passes through the first-conductivity-type semiconductor substrate in a depth direction, and is electrically connected to the second-conductivity-type collector layer; and
a first-conductivity-type high-concentration region that is provided from the one main surface of the first-conductivity-type semiconductor substrate within a depth of 20 μm or less from a bottom of the second-conductivity-type base region towards the second-conductivity-type collector layer,
wherein a ratio of the impurity concentration n₁ of the first-conductivity-type high-concentration region to the impurity concentration n₂ of the drift region satisfies 1.0<n₁/n₂≦5.0,
the method comprising:
a first thermal diffusion step of performing thermal diffusion for a thermal diffusion time, which is obtained by subtracting a thermal diffusion time required to diffuse the first-conductivity-type high-concentration region to a predetermined depth from a full diffusion time required to diffuse the second-conductivity-type isolation layer for obtaining a predetermined design breakdown voltage to a final depth, to form the second-conductivity-type isolation layer at a depth that is less than the final diffusion depth of the second-conductivity-type isolation layer; and
a second thermal diffusion step of performing thermal diffusion for a thermal diffusion time required to diffuse the first-conductivity-type high-concentration region to the predetermined depth to diffuse the first-conductivity-type high-concentration region to the predetermined depth, and at the same time to complete diffusing the second-conductivity-type isolation layer to the final depth, after the first thermal diffusion step.

6. The method for producing the semiconductor device according to claim 5, further comprising:
an implantation step of implanting first-conductivity-type impurity ions into the entire one main surface of the first-conductivity-type semiconductor substrate to form the first-conductivity-type high-concentration region after the first thermal diffusion step and before the second thermal diffusion step,
wherein, in the implantation step, the impurity ions are phosphorus ions and an implantation dose is in the range of 0.6×10¹² cm⁻² to 1.2×10¹² cm⁻², and
in the second thermal diffusion step, a thermal diffusion temperature is in the range of 1250° C. to 1350° C. and a thermal diffusion time is in the range of 30 hours to 60 hours.
